(19) United States
(12) Patent Application Publication
(10) Pub. No.: US 2007/0257264 A1
(43) Pub. Date: Nov. 8, 2007

(54) CATALYST-FREE GROWTH OF GaN NANOSCALE NEEDLES AND APPLICATION IN InGaN/GaN VISIBLE LEDS

(76) Inventors: Stephen D. Hersee, Albuquerque, NM (US); Xin Wang, Albuquerque, NM (US); Steven R.J. Brueck, Albuquerque, NM (US); Xinyu Sun, Albuquerque, NM (US)

Correspondence Address: MH2 TECHNOLOGY LAW GROUP, 1951 KIDWELL DRIVE, SUITE 550, TYSONS CORNER, VA, 22182, US

(21) Appl. No.: 11/559,214

(22) Filed: Nov. 13, 2006

Related U.S. Application Data
(60) Provisional application No. 60/735,198, filed on Nov. 10, 2005.

(51) Int. Cl. H01L 33/00; H01L 31/0256

(52) U.S. Cl. 257/76; 257/E51.02; 977/762

(57) ABSTRACT

Exemplary embodiments provide a scalable process for the growth of large scale and uniform III-N nanoneedle arrays with precise control of the position, cross sectional shape and/or dimensions for each nanoneedle. In an exemplary process, a plurality of nanoneedle array can be formed by growing one or more semiconductor material in a plurality of patterned rows of apertures with a predetermined geometry. The plurality of patterned rows of apertures can be formed though a thick selective nanoscale growth mask, which can later be removed to expose the plurality of nanoneedle arrays. The plurality of nanoneedle arrays can be connected top and bottom by a continuous coalesced epitaxial film, which can be used in a planar semiconductor process or be further configured as a photonic crystal to improve the output coupling of nanoscale optoelectronic devices such as LEDs and/or lasers.

### RELATED APPLICATIONS

This application claims priority from U.S. Provisional Patent Application Ser. No. 60/735,198, filed Nov. 10, 2005, which is hereby incorporated by reference in its entirety.

### FIELD OF THE INVENTION

This invention relates generally to light emitting diodes (LEDs), and, more particularly, to LEDs that include nanoneedle arrays.

### BACKGROUND OF THE INVENTION

Nanoscale needles, also referred to herein as nanowires, composed of group III-N alloys (e.g., GaN) provide the potential for new semiconductor device configurations such as nanoscale optoelectronic devices. If this potential is to be fully realized, a scalable process is required to form high quality group III-N nanoneedles with precise control of the geometry and position of each nanoneedle.

Conventional nanoneedle preparation is based on the vapor-liquid-solid (VLS) growth mechanism and involves the use of catalysts such as Au, Ni, Fe, or In. Problems arise, however, because these conventional catalytic processes cannot control the position and uniformity of the resulting nanoneedles.

A further problem with conventional catalytic processes is that the catalyst is inevitably incorporated into the nanoneedles. This degrades the crystalline quality of the resulting nanostructures, which limits their applications.

Thus, there is a need to overcome these and other problems of the prior art and to provide a catalytic free process to form high-quality nanoscale needles with well-defined locations and dimensions. It is further desirable to provide a scalable process that can provide large scale and uniform nanoneedle arrays.

### SUMMARY OF THE INVENTION

According to various embodiments, the present teachings include a method of making nanoneedles. In the method, a growth mask layer can be formed over a buffer layer formed over a semiconductor substrate. A plurality of patterned apertures can be formed through the growth mask layer to expose a plurality of portions of a surface of the buffer layer. A semiconductor material can then be filled in the plurality of patterned apertures, wherein each of the plurality of patterned apertures has a width of about 200 nm or less. A plurality of nanoneedles can then be formed by removing the growth mask layer and exposing the filled semiconductor material.

According to various embodiments, the present teachings also include a nanoneedle array including a selective growth mask layer over a buffer layer that is disposed over a semiconductor substrate. A plurality of nanoneedles with a minor dimension of about 200 nm or less can be disposed on the buffer layer and protrude through the growth mask layer.

According to various embodiments, the present teachings also include a method for making a light emitting diode. In this method, the plurality of nanoneedles can be formed in a multiple quantum well (MQW) structure that is formed over a first doped layer having a first conductivity type. The first doped layer can be formed over a semiconductor substrate. A second doped layer having a second conductivity type can be formed over the MQW structure, wherein the second conductivity type is opposite the first conductivity type. A third doped layer having the second conductivity type is also formed over the second doped layer.

According to various embodiments, the present teachings also include a light emitting diode. In the light emitting diode, a first doped layer can include a first conductivity type stacked over a semiconductor substrate. A multiple quantum well (MQW) structure can be formed over the first doped layer and include the plurality of nanoneedle arrays. A second doped layer can be formed over the MQW structure and have a second conductivity type opposite to the first conductivity type.

According to various embodiments, the present teachings further include a light emitting diode including an n-type GaN layer stacked over a semiconductor substrate and a GaN buffer layer disposed between the n-type GaN layer and the semiconductor substrate. The light emitting diode can also include a plurality of nanoneedles formed of one or more of GaN, InGaN, AlGaN, and AlInGaN in a multiple quantum well (MQW) structure stacked over then-type GaN layer. The light emitting diode can further include a p-type AlGaN layer stacked over the MQW structure and a p-type GaN layer stacked over the p-type AlGaN layer.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIGS. 1A-1D depict cross-sectional views of an exemplary semiconductor nanoneedle device at various stages of fabrication in accordance with the present teachings.

FIG. 2 is an exemplary schematic for a plurality of nanoneedle arrays grown by using a selective growth mask without use of a catalyst in accordance with the present teachings.

FIG. 3 depicts an exemplary result for a partial coalescence of a plurality of nanoneedle arrays grown in accordance with the present teachings.

FIG. 4 depicts a cross-sectional layered structure of an exemplary LED device in accordance with the present teachings.

### DESCRIPTION OF THE EMBODIMENTS

Reference will now be made in detail to exemplary embodiments of the invention, an example of which is illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any give or particular function. Furthermore, to the extent that the terms “including”, “includes”, “having”, “has”, “with”, or variant thereof are used in either the detailed description and the claims, such terms are intended to be inclusive in a manner similar to the term “comprising”. The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Exemplary embodiments provide a scalable process for the growth of high-quality III-N nanoneedles and uniform nanoneedle arrays, in which the position, shape, diameter and/or the length of each nanoneedle can be precisely controlled. Specifically, a plurality of nanoneedle arrays can be formed by growing one or more of semiconductor materials in a plurality of patterned rows of apertures with a predetermined geometry. The plurality of patterned rows of apertures can be formed, for example, by MOCVD, through a thick selective nanoscale growth mask, which can later be removed to expose the plurality of nanoneedle arrays.

In addition, the plurality of nanoneedle arrays can be terminated with a continuous, epitaxial, and fully coalesced semiconductor contact layer. For example, as the plurality of nanoneedle arrays emerge from the selective growth mask, they can spread sideways (i.e., by lateral growth) and eventually forming a coalesced planar layer above the plurality of nanoneedles. This structure can be used as nanoneedle active region. The nanoneedle active region can be configured as a photonic crystal in the applications of nanoscale optoelectronic devices such as LEDs and/or lasers, providing improved internal quantum efficiency (e.g., low defect density and no Indium segregation) and improved light extraction.

As used herein, the term “nanoscale needles” or “nanoneedles” generally refers to any elongated conductive or semiconductive material that includes at least one minor dimension, for example, width or diameter, less than 500 nm. In various embodiments, the minor dimension can be less than 100 nm. The nanoneedles can also have an aspect ratio (e.g., length:width and/or major dimension:minor dimension) greater than 10.

Although the term “nanoneedles” is referred to throughout the description herein for illustrative purposes, it is intended that the term also encompass other elongated structures of like dimensions including, but not limited to, nanoshafts, nanopillars, nanowires, nanorods, and nanotubes (e.g., single wall nanotubes, multiwall nanotubes), and their various functionalized and derivatized fibril forms, which include nanofibers with exemplary forms of thread, yarn, fabrics, etc.

The nanoneedles can have various cross sectional shapes, such as, for example, rectangular, polygonal, oval, or circular shape. Accordingly, the “nanoneedles” can have cylindrical and/or cone-like 3-D shapes. In various embodiments, a plurality of “nanoneedles” can be, for example, substantially parallel, arcuate, sinusoidal, etc.

The nanoneedles can be formed from a substrate or a support. The substrate/support can be constructed from a variety of materials including Si, SiC, sapphire, III-V semiconductor compounds such as GaN, GaAs, metals, ceramics or glass.

In various embodiments, the nanoneedles can be formed using a III-V compound semiconductor materials system, for example, III-N compound materials system. In these materials systems, examples of the group III element can include Ga, In or Al, which can be formed from exemplary group III precursors, such as trimethylgallium (TMGa) or triethylgallium (TEGa), trimethylindium (TMIn) or trimethylaluminum (TMAI). Exemplary N precursors can be, for example, ammonia (NH₃). Other group V elements can also be used, for example, P or As, with exemplary group V precursors, such as tertiarybutylphoshine (TBP), or arsine (AsH₃). In various embodiments, many different III-V semiconductor alloy compositions can be used, based on the known relationships between bandgap energy and lattice constant of different III-V compounds.

In the following description, III-N semiconductor alloy compositions can be described by the combination of III-N elements, such as, for example, InGaN, GaN, AlGaN, AlInGaN. Other III-V compounds include, but are not limited to, InGaAs, AlGaAs, AlGaInAs, GaNAs, InGaAsP, or GaInNAs. Generally, the elements in a composition can be combined with various molar fractions. For example, the semiconductor alloy composition InGaN can stand for In₍ₓ₎Ga₍₁₋ₓ₎N, where the molar fraction, x, can be any number less than 1.00. In addition, depending on the molar fraction value, various active devices can be made by similar compositions. For example, an In_{0.3}Ga_{0.7}N (where x is about 0.3) can be used in the MQW active region of LEDs for a blue emission, while an In_{0.43}Ga_{0.57}N (where x is about 0.43) can be used in the MQW active region of LEDs for a green emission.

In various embodiments, the nanoneedles can include a dopant from a group consisting of: a p-type dopant from Group III of the periodic table, for example B, Al and In; an n-type dopant from Group V of the periodic table, for example P, As and Sb; a p-type dopant from Group II of the periodic table, for example, Mg, Zn, Cd and Hg; a p-type dopant from Group IV of the periodic table, for example, C; or an n-type dopant selected from a group consisting of: Si, Ge, Sn, S, Se and Te.

In various embodiments, the nanoneedles can have heterogeneous structures and be formed by various crystal growth techniques including, but not limited to, metal-organic chemical vapor deposition (MOCVD), molecular-beam epitaxy (MBE), gas source MBE (GSMBE), metal-organic MBE (MOMBE), atomic layer epitaxy (ALE), hydride vapor phase epitaxy (HVPE), or organometallic vapor phase epitaxy (OMVPE). In various embodiments, the growth rates of nanoneedles can be orientation dependent.

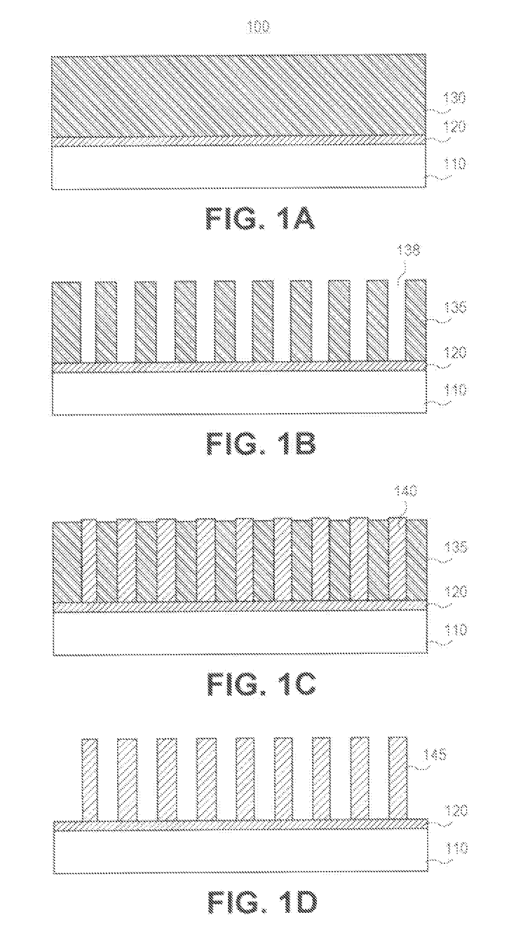

FIGS. 1A-1D depict cross-sectional views of an exemplary semiconductor nanoneedle device 100 at various stages of fabrication in accordance with the present teachings. It should be readily obvious to one of ordinary skill in the art that the nanoneedle device 100 depicted in FIG. 1 represents a generalized schematic illustration and that other layers/nanoneedles may be added or existing layers/nanoneedles may be removed or modified.

As shown in FIG. 1A, the device 100 can include stacked layers including a substrate 110, a buffer layer 120, and a growth mask layer 130. The substrate 110 can be a semiconductor substrate, such as, for example, sapphire, silicon carbide, or silicon. In various embodiments, a silicon-on-insulator (SOI) can be used for the substrate 110.

The buffer layer 120 can be formed over the substrate 110. The buffer layer 120 can be formed of, for example, GaN or AlGaN, using, for example, standard MOCVD. The thickness of the buffer layer 120 can be about 200 to 600 nm. In an additional example, the thickness of the buffer layer 120 can be, for example, about 60 nm.

The growth mask layer 130 can be formed over the buffer layer 120. The growth mask layer 130 can be formed of, for example, silicon nitride, silicon oxide or silicon carbide with an exemplary thickness of about 0.1-10 μm. In an additional example, the thickness of the growth mask layer 130 can be, for example, about 0.1-2 μm. The growth mask layer 130 can be formed by for example, LPCVD or PECVD known to one of ordinary skill in the art.

As shown in FIG. 1B, a growth mask 135 can be formed to provide a plurality of patterned rows of apertures 138 through the growth mask layer 130 and exposing a plurality of portions of the surface of the beneath buffer layer 120. The plurality of patterned rows of apertures 138 can have a thickness of the growth mask 135 of, for example, 800 nm, and a cross sectional dimension such as a width of, for example, about 100 nm. In another example the growth mask 135 can have a thickness of, for example, 200 nm and a cross sectional dimension of, for example, about 30 nm. Such nanoscale features can then be transferred to the subsequent process for the formation of nanoneedles. The plurality of patterned rows of apertures 138 can be formed by patterning and etching the growth mask layer 130 by, for example, one or more of interferometric lithography (IL) techniques or nanoimprint lithography (NL) techniques. Accordingly, in various embodiments, the aspect ratio of the apertures can be about 10 or less, such that nanoneedles with an aspect ratio of about 10 or less can be subsequently formed.

Specifically, interferometric lithography (IL) is a lithographic process that involves interference patterns of two (or more) mutually coherent light waves. The angles between the light propagation vectors of the waves are sufficiently large to produce an interference pattern that has a high spatial frequency. Suitable wavelengths for the IL process include, but are not limited to, I-line (364 nm Ar-ion laser and 355 nm tripled YAG laser); 244 nm (doubled Ar-ion); and 213/193 (fifth harmonic YAG/ArF laser). In various embodiments, various IL techniques, for example, immersion IL or nonlinear IL can be used to fabricate the plurality of patterned rows of apertures 138 for a reduced dimension.

Nanoimprint lithography is a lithographic process that involves a stamp having embossed nanostructures. The stamp can be pressed onto, for example, the growth mask layer 130 at high temperature and then released from the growth mask layer 130 when it is cooled to a low temperature. Thus, the growth mask layer 130 can be imprinted with the negative patterns of nanostructures of the stamp to form the plurality of the patterned rows of apertures 138.

In addition, IL and/or NL can produce nanostructures or patterns of nanostructures over wide, macroscopic areas. Further, IL or NL can be used to generate arrays of nanostructures (e.g., protrusions or channels) whose dimensions vary semi-continuously in the plane of the surface of the material being patterned.

FIG. 1C, a plurality of semiconductor nanostructures 140 can be formed by growing one or more semiconductor materials to fill the plurality of patterned rows of apertures 138 defined by the patterned growth mask 135. The patterned growth mask 135 can serve as a selective growth mold to negatively replicate its nanopatterns from the plurality of patterned rows of apertures 138 to the plurality of semiconductor nanostructures 140, which can fill all available growth area of the apertures from the exposed portions of the surface of the buffer layer 120. In various embodiments, the semiconductor materials can include one or more of GaN, InGaN, AlInGaN and AlGaN.

In this manner, the position, the cross sectional shape, and the dimensions of each of the plurality of semiconductor nanostructures 140 can be determined by the patterns and the cross sectional shapes of each of the plurality of patterned rows of apertures 138. For example, the plurality of patterned rows of apertures 138 can include a hexagonal array with a dimension of about 500 nm pitch. The hexagonal array can then be transferred to the growth of the plurality of semiconductor nanostructures 140 with a similar or smaller dimension of about 500 nm pitch or less. In another example, if the one or more apertures of the plurality of patterned rows of apertures 138 are approximately circular with an exemplary diameter of about 220 nm, one or more nanostructures of the plurality of semiconductor nanostructures 140 can be grown in the circular apertures with a similar diameter of about 220 nm or less. Thus, the plurality of the semiconductor nanostructures 140 can be positioned in a well-defined location and shaped by the plurality of the patterned rows of apertures 138 in the growth mask 135.

In various embodiments, the plurality of patterned rows of apertures 138 in the growth mask 135 can be intentionally oriented along a certain crystal direction of the buffer layer 120. For example, during IL patterning, the rows of apertures in the growth mask 135 can be intentionally oriented along <1100> directions of a GaN buffer layer. In an exemplary embodiment, when a GaN the buffer layer is grown on a sapphire substrate, there can be a 30°rotation about the c axis between the GaN buffer layer and the sapphire unit cells.

In various embodiments, because of the large-area nanoscale capability, the precisely controlled growth of the plurality of semiconductor nanostructures 140 can be formed in a large area, which can be readily extended to manufacturing requirements including automatic wafer handling and extended to larger size wafers for establishing efficacy of photonic crystals for light extraction from visible and near-UV LEDs.

In FIG. 1D, a plurality of nanoneedle arrays 145 can be formed by removing the growth mask layer 135 and exposing the plurality of semiconductor nanostructures 140. Accordingly, the length of the plurality of nanoneedle arrays 145 can be determined by the thickness of the growth mask layer 135. For example, the length of the plurality of nanoneedle arrays 145 can be, for example, about 0.1-10 μm, and as an additional example, can be about 0.1-2 μm. The plurality of nanoneedle arrays 145 can maintain the features from the plurality of semiconductor nanostructures 140. For example, the plurality of nanoneedle arrays 145 can be formed of, for example, GaN, InGaN, AlInGaN, or AlGaN. In various embodiments, heterostructures can be formed for each nanoneedle of the plurality of nanoneedle arrays 145. Examples include, but are not limited to, InGaN/GaN, AlInGaN/AlGaN, and/or AlGaN/GaN. In various other embodiments, n-type and/or p-type doping can be incorporated into the plurality of nanoneedle arrays 145.

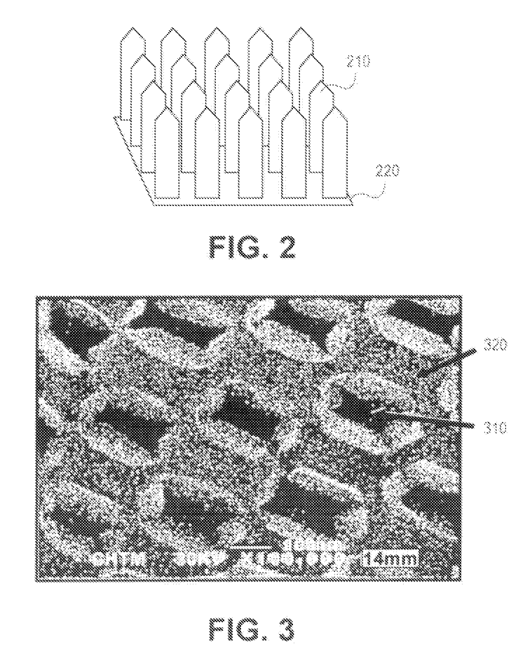

FIG. 2 is an exemplary schematic for a plurality of ordered nanoneedle arrays 210 grown by using a selective growth without use of a catalyst. As shown, the plurality of ordered nanoneedle arrays 210 can be formed on a substrate 220 by removing the selective growth mask (not shown) to reveal the plurality of the nanoneedle arrays 210. The selective growth mask can be removed by suitable etch process known to one of ordinary skill in the art, for example, a wet chemical etching. In various embodiments, the nanoneedle arrays can be orientated along certain crystal direction with single crystal feature. In various other embodiments, the nanoneedle diameter (i.e., minor dimension) can be, for example, about 30-100 nm and the array pitch for the plurality of nanoneedle arrays 140 can be, for example about 100-200 nm.

There are many potential applications of III-N nanoneedles and nanoneedle arrays, for example, in nanoscale optoelectronic devices, such as, LEDs and lasers. However, problems arise with conventional applications having isolated nanoneedles because contacting nanoneedles requires an extremely precise processing capability.

In accordance with present teachings, the plurality of the ordered and isolated nanoneedle arrays disclosed herein can be capped by fully coalescing with a continuous, epitaxial semiconductor contact layer and be free of barrier effects. For example, during the formation of the plurality of nanoneedle arrays, when the growth is continued such that the plurality of nanoneedle arrays can emerge from the thick growth mask, each nanoneedle can begin to grow laterally as well as vertically. If the growth is continued further, the plurality of nanoneedle arrays can be coalesced to form a continuous epitaxial layer above the plurality of nanoneedle arrays and form nanoneedle active region.

In various embodiments, the nanoneedle active region can be connected top and bottom by a continuous coalesced epitaxial film, which can be used in normal (e.g., planar) semiconductor processes. For example, continuous doped, cladding layers and electrical contact layers can then be created above the nanoneedle active region. The nanoneedle active region can also be configured as a photonic crystal to improve the output coupling of nanoscale optoelectronic devices such as LEDs and/or lasers. The exemplary devices can have low defect density and no indium segregation which can in turn improve internal quantum efficiency and light extraction

In various embodiments, the coalescence of the isolated nanoneedles can be achieved by a nanoscale heteroepitaxy (NHE) process. NHE is a technique for the growth of thin films in a manner which localizes and apportions strain at the substrate-epilayer or epilayer-epilayer interface, and enables strain to decay significantly with increasing epilayer thickness after the epitaxial film growth. The NHE techniques can be used for lattice-mismatched heteroepitaxy growth, for example, lateral epitaxial overgrowth, pendeo-epitaxy and cantilever-epitaxy. In addition, the NHE techniques can provide a homogenous defect reduction across the entire wafer, for example, allowing regular, unrestricted processing on these wafers and the full cost benefits of scaleability.

FIG. 3 shows an exemplary result for partially coalesced nanoneedle arrays 310 grown in accordance with the present teachings. FIG. 3 also shows coalesced area 320 formed on a selective growth mask (not shown) by, for example, a NHE process. Full coalescence (not shown) can further be achieved by a continued growth. In various embodiments, the selective growth mask can be removed and revealing a plurality of capped nanoneedle arrays 310.

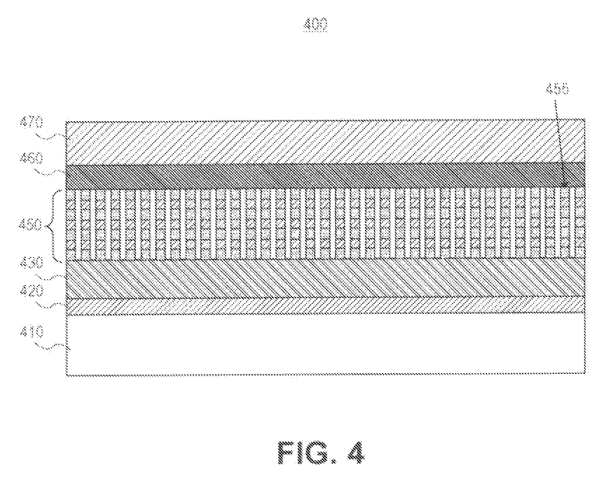

One application for the capped nanoneedle arrays is to incorporate them into, for example, the MQW active regions of visible LEDs. This can provide a low defect density and can improve In-clustering effects in the active regions. FIG. 4 depicts a cross-sectional layered structure of an exemplary LED device 400 in accordance with the present teachings. It should be readily obvious to one of ordinary skill in the art that the device 400 depicted in FIG. 4 represents a generalized schematic illustration and that other layers may be added or existing layers may be removed or modified.

As shown, the LED device 400 can include a layered structure including a substrate 410, a buffer layer 420, a first doped layer 430, a MQW structure 450, a second doped layer 460, and a third doped layer 470.

The substrate 410 can be a semiconductor substrate, such as, for example, sapphire, silicon carbide, or silicon. In various embodiments, a silicon-on-insulator (SOI) can be used for the substrate 410.

The buffer layer 420 can be formed over the substrate 110. The buffer layer 120 can be formed of, for example, GaN or AlGaN, by various crystal growth methods known to one of ordinary skill in the art.

The first doped layer 430 can be a compliant layer with a thickness of, for example, about 50 nm to 500 nm. The first doped layer 430 can be formed of, for example, GaN, which can be made an n-type epilayer by doping with various impurities such as silicon, germanium, selenium, sulfur and tellurium. In various embodiments, the first doped layer 130 can be made a p-type layer by introducing beryllium, strontium, barium, zinc, or magnesium. Other dopants known to one of ordinary skill in the art can be used.

The MQW structure 450 can be formed over the first doped layer 430 and include a plurality of nanoneedles 455, which can be fully coalesced by the second doped layer 460. The plurality of nanoneedles 455 can be formed using a selective growth mask (not shown) as described herein. One or more of the plurality of nanoneedles 455 can have heterostructures, for example, with alternating layers of InGaN and GaN or two InGaN layers having different compositions, and alternatively, with alternating layers of AlInGaN and AlGaN or two AlInGaN layers having different compositions.

The plurality of nanoneedles 455 can have various cross sectional shape, such as, for example, polygonal, rectangular, oval, and circular as described herein. The cross sectional dimensions of the plurality of nanoneedles 455 can be similar to the cross sectional dimensions of Indium-rich clusters in the MQW structure. The dimensions of In-rich clusters can be, for example, about 5-50 nm. In various embodiments, the MQW structure 450 including the plurality of nanoneedles 455 can have a defect density of about 10 ⁸ cm⁻² or less.

The second doped layer 460 can be formed on the MQW structure 450 by coalescing the plurality of nanoneedles 455 using, for example, nanoscale heteroepitaxy (NHE) techniques. The second doped layer 460 can be a layer with sufficient thickness to keep indium clusters within the MQW structure 450. The thickness of the layer 460 can be, for example, about 500 to about 2000 nm. The second doped layer 460 can be formed of, for example, AlGaN. The second doped layer 460 can be doped with a conductivity type similar to the third doped layer 470.

The third doped layer 470 can be formed over the second layer 460 to cap the LED device 400. The third doped layer 470 can be formed of, for example, GaN and doped to be an n-type or p-type. In various embodiments, if the first doped layer 430 is an n-type layer, the layer 460 and/or 470 can be a p-type layer and vice versa. The third doped layer 470 can have a thickness of about 50-500 nm.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of making nanoneedles comprising:
providing a semiconductor substrate;
forming a buffer layer over the semiconductor substrate;
forming a growth mask layer over the buffer layer;
forming a plurality of patterned apertures through the growth mask layer to expose a plurality of portions of a surface of the buffer layer, wherein each of the plurality of patterned apertures has a width of about 200 nm or less;
filling the plurality of patterned apertures with a semiconductor material; and
forming a plurality of nanoneedles by removing the growth mask layer and exposing the filled semiconductor material.

2. The method of claim 1, wherein forming the plurality of patterned apertures comprises using one or more of nanoimprint lithography, interferometric lithography, immersion interferometric lithography, and nonlinear interferometric lithography.

3. The method of claim 1, wherein the plurality of nanoneedles have a thickness of about 0.1 to about 10 μm and an aspect ratio of about 10 or less.

4. The method of claim 1, wherein one or more of the plurality of patterned apertures has a cross sectional shape selected from the group consisting of a polygon, a rectangle, an oval, and a circle.

5. The method of claim 1, wherein the semiconductor material for the plurality of nanoneedles comprises one or more of GaN, InGaN, AlInGaN and AlGaN.

6. The method of claim 1, further comprising coalescing the plurality of nanoneedles by nanoheteroepitaxy.

7. The method of claim 1, further comprising configuring the plurality of nanoneedles as a photonic crystal in one or more of light emitting diodes and lasers.

8. A nanoneedle array comprising:
a buffer layer over a semiconductor substrate;
a growth mask layer over the buffer layer; and
a plurality of nanoneedles disposed on the buffer layer and formed by growing through and then removing the growth mask layer, wherein each of the plurality of nanoneedles has a minor dimension of about 200 nm or less.

9. The nanoneedle array of claim 8, wherein the buffer layer comprises a material selected from the group consisting of GaN, and AlGaN.

10. The nanoneedle array of claim 8, wherein the growth mask layer comprises a material selected from the group consisting of silicon nitride, silicon oxide, and silicon carbide.

11. The nanoneedle array of claim 8, wherein the plurality of nanoneedles comprises a material selected from the group consisting of GaN, AlGaN, InGaN, and AlInGaN.

12. The nanoneedle array of claim 8, wherein one or more of the plurality of nanoneedles comprises heterostructures.

13. The nanoneedle array of claim 8, wherein the plurality of nanoneedles further have a minor dimension of about 30 nm or less.

14. The nanoneedle array of claim 8, wherein the plurality of nanoneedles have a length of about 0.1 to about 10 μm or more.

15. The nanoneedle array of claim 8, wherein the plurality of nanoneedles have a cross sectional shape of one or more of a polygon, a rectangle, an oval, and a circle.

16. A method for making a light emitting diode comprising:
forming a first doped layer having a first conductivity type over a semiconductor substrate;
forming the plurality of nanoneedles of claim 1 in a multiple quantum well (MQW) structure over the first doped layer;
forming a second doped layer having a second conductivity type over the MQW structure, wherein the second conductivity type is opposite to the first conductivity type; and
forming a third doped layer having the second conductivity type over the second doped layer.

17. The method of claim 16, further comprising forming a buffer layer between the first doped layer and the semiconductor substrate.

18. The method of claim 16, wherein forming the second doped layer comprises coalescing the plurality of nanoneedles.

19. The method of claim 16, wherein forming the second doped layer comprises using nanoheterepitaxy.

20. A light emitting diode comprising:
a semiconductor substrate;
a first doped layer over the semiconductor substrate, wherein the first doped layer comprises a first conductivity type;
a multiple quantum well (MQW) structure over the first doped layer, wherein the MQW structure comprises the plurality of nanoneedle arrays of claim 8; and
a second doped layer over the MQW structure, wherein the second doped layer comprises a second conductivity type opposite to the first conductivity type.

21. The light emitting diode of claim 20, further comprising:
a buffer layer disposed between the semiconductor substrate and the first doped layer; and
a third doped layer comprising the second conductivity type over the second doped layer.

22. The light emitting diode of claim 20, wherein each of the first doped layer and second doped layer comprises one or more of GaN and AlGaN.

23. The light emitting diode of claim 20, wherein cross sectional dimensions of the plurality of nanoneedles is similar to cross sectional dimensions of In-rich clusters in the MQW structure.

24. The light emitting diode of claim 20, wherein the MQW structure has a defect density of about 10 ⁸ cm⁻² or less.

25. A light emitting diode comprising:
an n-type GaN layer over a semiconductor substrate, wherein a GaN buffer layer is disposed between the n-type GaN layer and the semiconductor substrate;
a plurality of nanoneedles comprising one or more of GaN, InGaN, AlGaN, and AlInGaN stacked over the n-type GaN layer in a multiple quantum well (MQW) structure;
a p-type AlGaN layer stacked over the MQW structure; and
a p-type GaN layer stacked over the p-type AlGaN layer.
